(19) United States
(12) Patent Application Publication
(10) Pub. No.: US 2019/0369166 A1
(43) Pub. Date: Dec. 5, 2019

(54) EXTENDING BATTERY LIFE IN BEHIND THE METER BATTERY ENERGY STORAGE SYSTEMS

(71) Applicant: NEC Laboratories America, Inc., Princeton, NJ (US)

(72) Inventors: Ramin Moslemi, Sunnyvale, CA (US); Ali Hooshmand, San Jose, CA (US); Ratnesh Sharma, Fremont, CA (US)

(21) Appl. No.: 16/410,533

(22) Filed: May 13, 2019

Related U.S. Application Data
(60) Provisional application No. 62/678,311, filed on May 31, 2018.

(51) Int. Cl. G01R 31/392; H02J 7/00; H02J 7/04

(52) U.S. Cl. CPC G01R 31/392; H02J 2003/003; H02J 7/042; H02J 7/0057

(57) ABSTRACT

Systems and methods for demand charge minimized operations while extending battery life, including determining a demand charge threshold based on received historical data. The systems and methods further including generating a charging pattern for a battery array from the historical. The systems and methods further including calculating a charging schedule for the battery array based on the demand charge threshold, a short term load profile, and the charging pattern. The charging schedule being calculated to follow the charging pattern without exceeding the demand charge threshold and transmitting commands to a battery controller in accordance with to the charging schedule.

### RELATED APPLICATION INFORMATION

This application claims priority to provisional application No. 62/678,311, filed on May 31, 2018, incorporated herein by reference herein its entirety.

### BACKGROUND

### Technical Field

The present invention relates to the management of energy storage systems, and more particularly to management of behind-the meter energy storage systems for demand charge minimization while extending battery life.

### Description of the Related Art

Commercial and industrial entities are consistently plagued by their energy costs. These corporations are dependent on the local utility company to meet their energy needs. The utility company will monitor the corporation's power consumption over a period of time and then bill them accordingly. The utility company will apply an additionally charge due to maximum demand peaks throughout a billing cycle.

### SUMMARY

According to an aspect of the present invention, a method is provided for demand charge minimized operations while extending battery life, including determining a demand charge threshold based on received historical data. The method further including generating a charging pattern for a battery array from the historical data. The generating further including simulating a power consumption of a load over a period of time from the historical data, extracting a charge profile and a peak shaving profile from the simulation, and learning a charging pattern from the charge profile and the peak shaving profile. The charging pattern including optimal charging and discharging commands to minimize demand charge violations and minimize a state of charge of the battery array. The method further including calculating a charging schedule for the battery array based on the demand charge threshold, a short term load profile. The charging schedule being calculated to follow the charging pattern without exceeding the demand charge threshold and transmitting commands to a battery controller in accordance with to the charging schedule.

According to another aspect of the present invention, a system is provided for demand charge minimized operations while extending battery life, including a processor device operatively coupled to a non-transitory computer-readable storage medium, the processor being configured to determine, using a secondary control layer, a demand charge threshold based on received historical data. The processor is further configured to generate, using a primary control layer, a charging pattern for a battery array from the historical data. Wherein to generate further including to simulate a power consumption of a load over a period of time from the historical data, extract a charge profile and a peak shaving profile from the simulation, and learn a charging pattern from the charge profile and the peak shaving profile. The charging pattern including optimal charging and discharging commands to minimize demand charge violations and minimize a state of charge of the battery array. The processor is further to calculate, using the primary control layer, a charging schedule for the battery array based on the demand charge threshold, a short term load profile, and the charging pattern. The charging schedule being calculated to follow the charging pattern without exceeding the demand charge threshold and to transmit, using a real time controller commands to a battery controller in accordance with to the charging schedule.

According to another aspect of the present invention, A non-transitory computer readable storage medium comprising a computer readable program for demand charge minimized operations while extending battery life, including determining a demand charge threshold based on received historical data. Further including generating a charging pattern for a battery array from the historical data. The generating further including simulating a power consumption of a load over a period of time from the historical data, extracting a charge profile and a peak shaving profile from the simulation, and learning a charging pattern from the charge profile and the peak shaving profile. The charging pattern including optimal charging and discharging commands to minimize demand charge violations and minimize a state of charge of the battery array. Further including calculating a charging schedule for the battery array based on the demand charge threshold, a short term load profile. The charging schedule being calculated to follow the charging pattern without exceeding the demand charge threshold and transmitting commands to a battery controller in accordance with to the charging schedule.

### BRIEF DESCRIPTION OF DRAWINGS

The disclosure will provide details in the following description of preferred embodiments with reference to the following figures wherein:

FIG. 1 is a block/flow diagram illustrating a system/method for management of a behind-the meter energy storage/management systems for demand charge minimization while extending battery life, in accordance with aspects of the present invention.

FIG. 2 is a block/flow diagram illustrating a system/method for the demand charge management circuitry according to embodiments of the present invention.

FIG. 3 is a block/flow diagram illustrating a system/method for the primary control layer according to embodiments of the present invention.

FIG. 4 is a block/flow diagram illustrating a high-level method for generating a charge/discharge schedule for the management of a behind-the meter energy storage/management systems for demand charge minimization while extending battery life, in accordance with the present invention.

FIG. 5 is a block/flow diagram illustrating an exemplary processing system to which the present principles may be applied, in accordance with the present invention;

### DETAILED DESCRIPTION OF PREFERRED EMBODIMENTS

In accordance with the present invention, systems and methods are provided for management of behind-the meter energy storage/management systems for demand charge minimization while extending battery life.

In one embodiment, to reduce the demand charges, an energy storage device (e.g., battery or battery array), controlled by a Behind-The-Meter (BTM) Energy Management System (EMS) can be implemented in accordance with aspects of the present invention. The BTM-EMS can exploit a battery array such that the peak consumption of power from a grid decreases and demand charges by the utility are reduced. The BTM-EMS can supply power to a load using the battery array when load demands are larger than a demand threshold. The BTM-EMS can also manipulate the charging/discharging schedule of the battery array to prolong the life span of the batteries while maintaining the demand charge minimization.

In various embodiments, the BTM-EMS can include a demand charge management circuitry. The demand charge management circuitry can include three layers, a secondary control layer, a primary control layer, and a real time controller for demand charge minimization while extending battery life in accordance with aspects of the present invention. The secondary control layer can estimate a demand charge threshold (DCT) for an upcoming billing period. The primary layer can generate a charge/discharge schedule for the battery array. The charge/discharge schedule can be generated using an ideal charge/discharge pattern, short term load data, and/or DCT values. The charge/discharge schedule can be generated with a main goal of minimizing DCT violations and with a secondary goal of minimizing the average state of charge (SOC) of the battery array (prolonging the lifespan of the batteries in the battery array). The real time controller can review the charge/discharge schedule and then implement the charge/discharge schedule with the battery array.

Moreover, the layers can influence the charging and discharging behavior of the battery array, which can significantly extend the lifespan of the batteries while maximize performance in accordance with various embodiments of the present invention. The battery State-of-Charge (SoC) and battery throughput are among a plurality of important battery operating conditions affected in and controlled by the real-time controller in accordance with aspects of the present invention.

In a useful embodiment, the demand charge management circuitry can continuously update the DCT values during a billing period and charge/discharge schedule accordingly. After establishing an ideal charge/discharge pattern, the demand charge management circuitry can generate a charge/discharge schedule based on the updated DCT values in the way that battery array charge/discharge schedule follows the calculated charge/discharge pattern. When generating the charge/discharge schedule, the demand charge management circuitry can attempt follows the ideal charge/discharge pattern as closely as possible without causing a DCT violation. The charge/discharge schedule can consider ideal charge/discharge pattern, the short term load forecast, battery conditions and/or updated DCT information. This can help meet demand charge minimization and SOC minimization, which will lower costs by lower energy costs and prolonging the lifespan of the batteries.

Embodiments described herein can be entirely hardware, entirely software or including both hardware and software elements. In a preferred embodiment, the present invention is implemented in software, which includes but is not limited to firmware, resident software, microcode, etc.

Embodiments can include a computer program product accessible from a computer-usable or computer-readable medium providing program code for use by or in connection with a computer or any instruction execution system. A computer-usable or computer readable medium can include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium can include a computer-readable storage medium such as a semiconductor or solid state memory, magnetic tape, a removable computer diskette, a random access memory (RAM), a read-only memory (ROM), a rigid magnetic disk and an optical disk, etc.

Each computer program can be tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system can also be considered to be embodied in a computer-readable storage medium, configured with a computer program, where the storage medium so configured causes a computer to operate in a specific and predefined manner to perform the functions described herein.

A data processing system suitable for storing and/or executing program code can include at least one processor coupled directly or indirectly to memory elements through a system bus. The memory elements can include local memory employed during actual execution of the program code, bulk storage, and cache memories which provide temporary storage of at least some program code to reduce the number of times code is retrieved from bulk storage during execution. Input/output or I/O devices (including but not limited to keyboards, displays, pointing devices, etc.) can be coupled to the system either directly or through intervening I/O controllers.

Network adapters can also be coupled to the system to enable the data processing system to become coupled to other data processing systems or remote printers or storage devices through intervening private or public networks. Modems, cable modem and Ethernet cards are just a few of the currently available types of network adapters.

Businesses can install behind-the meter energy storage/management systems (BTM-BESS) to reduce their overall energy costs. The BTM-BESS can provide power during peak loads and absorb energy demand peaks. Due to the unpredictable nature of energy demand, businesses can maximize the state of charge (SOC) of the battery system to absorb any unexpected peak loads. However, maximizing the SOC of the BTM-BESS puts unnecessarily strain on the batteries in the energy system and decreases their lifespan. The additional costs to replace the worn batteries jeopardizes the initial cost-savings of implementing the BTM-BESS in the first place.

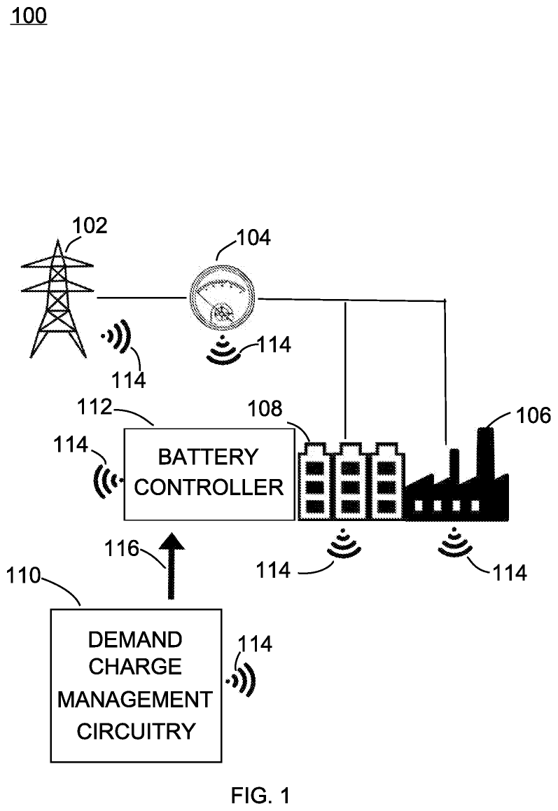

Referring now in detail to the figures in which like numerals represent the same or similar elements and initially to FIG. 1, a system/method 100 for management of behind-the meter energy storage/management systems for demand charge minimization while extending battery life is illustratively depicted in accordance with an embodiment of the present invention. In various embodiments, to reduce demand charges while maximizing the lifespan of the batteries, a behind-the-meter battery array can be controlled by an energy management system in accordance with aspects of the present invention. The energy management system can exploit the battery array such that the peak power demand from the utility decreases, and demand charges can be reduced. The energy management system can be embodied as a demand charge management circuitry and a battery controller. In various embodiments, the system 100 for managing the behind the meter energy storage/management system in accordance with embodiments of the present invention can include, e.g., a utility pole 102, a smart meter 104, an industrial load 106, a battery array 108, a demand charge management circuitry 110, a battery controller 112, a network 114, and commands 116.

In one example, the utility pole 102 can be electrically coupled to the smart meter 104, industrial load 106, and the battery array 108. The utility pole 102 can provide power to the industrial load 106 and the battery array 108 through the smart meter 104. In some embodiments, the utility pole 102 can be supplied by a local utility company. The local utility company can charge for the overall power consumption. The local utility company can also adjust charges based on when the power is consumed. In some embodiments, the local utility company can have an anytime period, a partial period, and a peak period. Each of the anytime period, partial period, and peak period can have a corresponding tariff. In some embodiments, the utility pole 102 can monitor the power consumption of the industry load 106 and the battery array 108. The utility pole 102 can provide the power consumption data to the demand charge management circuitry 110.

The smart meter 104 can be electrically coupled to the utility pole 102, the industrial load 106, and the battery array 108. The smart meter 104 can be embodied as any type of meter that can perform the functions herein. The smart meter 104 can record the power consumed by the industrial load 106 and the battery array 108 from the utility pole 102. The smart meter 104 can provide the recorded power consumption to the local utility company. In some embodiments, the smart meter 104 can store power consumption records over a period of time. In some embodiments, the smart meter 104 can be coupled to the demand charge management circuitry 110 and the battery controller 112 over the network 114. In some embodiments, the smart meter 104 can provide the demand charge management circuitry 110 and the battery controller 112 with historical data. The historical data can relate to the power consumption of the industrial load 106 and the battery array 108 over a period of time. In some embodiments, the historical data can relate to the power consumed by the industrial load 106 and the battery array 108 over an ideal billing period. In some embodiments, the smart meter 104 can transmit real time power consumption data to the demand charge management circuitry 110.

The industrial load 106 can be electrically coupled to the smart meter 104 and the battery array 108. The industrial load 106 can be embodied as any type of load which consumes power. In some embodiments, the industrial load 106 can be embodied as a commercial building, a factory, a datacenter, an office building, etc. The industrial load 106 can consume power provided by the utility pole 102 and/or the battery array 108.

In some embodiments, the industrial load 106 can include a power generating system. The power generating system can be embodied as solar panels or any other type of power generating system. In some embodiments, the industrial load 106 can record its power consumption of a period of time. In some embodiments, the industrial load 106 can communicate with the demand charge management circuitry 110 over the network 114. The industrial load 106 can provide the demand charge management circuitry 110 with records relating to its power consumption over a time period. In some embodiments, the records can indicate if the power was provided by the utility pole 102 or the battery array 108. In some embodiments, the industrial load 106 can provide real time power consumption data to the demand charge management circuitry 110. In some embodiments, the industrial load 106 can provide a schedule of activities to be preformed and the power consumed by each activity to the demand charge management circuitry 110.

The battery array 108 can be electrically coupled to the to the smart meter 104 and the industrial load 106. The battery array 108 can be embodied as any type of energy storage system that can perform the function herein. The battery array 108 can be embodied as a grouping of individual batteries. The battery array 108 can supply power to the industrial load 106 to reduce peak energy demands. In some embodiments, the battery array 108 can supply power to the industrial load 106 to keep the net load below a demand charge threshold. The battery array 108 can be charged by the utility pole 102 through the smart meter 104. In some embodiments, each battery in the battery array 108 can be controlled individually. In some embodiments, the battery array 108 can record the periods of charge and the periods of discharge.

The battery array 108 can be connected to the demand charge management circuitry 110 and the battery controller 112 over the network 114. In some embodiments, the battery array 108 can supply the demand charge management circuitry 110 with the recorded charge/discharge data. In some embodiments, the battery array 108 can provide real time data to the demand charge management circuitry 110 along with data relating to the health of the battery array 108. In some embodiments, the battery array 108 can receive commands 116 from the battery controller 112. The commands 116 can dictate when the battery array 108 should charge/discharge itself. The commands 116 can also dictate a charge percentage to which the battery array 108 should be charged. In some embodiments, the commands 116 can be different for each individual battery in the battery array 108.

The demand charge management circuitry 110 can be connected to the smart meter 104, the industrial load 106, the battery array 108 and the battery controller 112 over the network 114. The demand charge management circuitry 110 can be embodied as any type of computing device that can perform the functions herein. The demand charge management circuitry 110 can receive data relating to power consumption from the smart meter 104, the industrial load 106, the battery array 108 and the battery controller 112. The demand charge management circuitry 110 can also receive charge/discharge data from the battery array 108 and/or the battery controller 112. The demand charge management circuitry 110 can estimate a demand charge threshold (DCT) for the upcoming billing period. In some embodiments, the DCT can be estimated using long term load forecasting, short term load forecasting, real time data, and/or machine learning. The demand charge management circuitry 110 can learn the optimal daily charging/discharging intervals from the received charge/discharged data and other historical data.

The demand charge management circuitry 110 can generate a charge/discharge pattern with goals of minimizing DCT violations and minimizing the State of Charge (SOC) of the battery array 108. The charge/discharge pattern can suggest a daily time windows for battery array charge and discharge to minimize DCT violations and minimize the State of Charge (SOC) of the battery array 108. In some embodiments, the demand charge management circuitry 110 can generate the charge/discharge pattern with a primary goal of minimizing DCT violations and a secondary goal of minimizing the State of Charge (SOC) of the battery array 108. In some embodiments, the secondary goal can be to minimize the average SOC of the battery array 108. In some embodiments, the demand charge management circuitry 110 can adjust the DCT and the charge/discharge pattern. The DCT and the charge/discharge pattern can be adjusted to prevent DCT violations, in response to short term load forecast data, in response to real time power consumption data, in response to potential predicted DCT violations, in response to battery condition data, and/or to add a level of robustness. The charge/discharge pattern can represent the ideal charging pattern for the battery array 108 for minimizing DCT violations and minimizing the State of Charge (SOC) of the battery array 108.

The demand charge management circuitry 110 can calculate a charge/discharge schedule. The charge/discharge schedule can be implemented with the battery array 108. The charge/discharge schedule can be calculated according to the charge/discharge pattern without causing any DCT violations. The violations can be embodied as demand charge threshold violations which can result in reducing demand charge savings. The charge/discharge schedule can be recalculated after a period of time. In some embodiments, the charge/discharge schedule will be recalculated every 15 minutes. The demand charge management circuitry 110 can transmit the charge/discharge schedule to the battery controller 112 as commands 116 over the network 114.

The battery controller 112 can be connected to the battery array 108 and the demand charge management circuitry 110 over the network 114. The battery controller 112 can be embodied as any type of computing device that can perform the functions herein. The battery controller 112 can control the charging/discharging of the battery array 108. The battery controller 112 can receive commands 116 on when the charging/discharging of the battery array 108 should occur from the demand charge management circuitry 110. In some embodiments, the battery controller 112 can charge the battery array 108 to a specific charge level. In some embodiments, the battery controller 112 can control the individual charging of each battery in the battery array 108. In some embodiments, the battery controller 112 can record the health of each battery in the battery array 108 and transmits the data the demand charge management circuitry 110.

The network 114 can provide a communication path for the utility pole 102, the smart meter 104, the industrial load 106, the battery array 108, the demand charge management circuitry 110, and the battery controller 112. The network 114 can be embodied as any type of network that can perform the functions herein. In some embodiments, the network can be a hard-wired network or a wireless network. The network 114 can allow for data to be transmitted between the utility pole 102, the smart meter 104, the industrial load 106, the battery array 108, the demand charge management circuitry 110, and the battery controller 112.

The commands 116 can instruct the battery array 108 to charge or discharge. The commands 116 are transmitted from the demand charge management circuitry 110 to the battery controller 112 over the network 114. The battery controller 122 can implement the commands 116 with the battery array 108. In some embodiments, the commands 116 can instruct the battery array 108 to charge or discharge for a period of time. In some embodiments, the commands 116 can instruct the battery array 108 to charge or discharge to a specific charge percentage. In some embodiments, the commands 116 can instruct the battery array 108 to charge individual batteries. In some embodiments, the commands 116 can instruct the battery array 108 to charge each battery in the battery array 108 to a specific charge level.

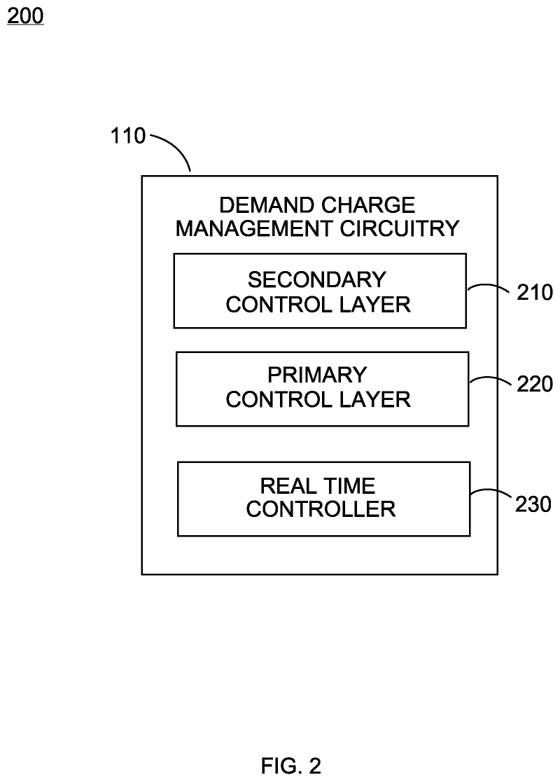

Referring now to FIG. 2, the demand charge management circuitry 110 can include a secondary control layer 210, a primary control layer 220, and a real time controller 230. Each of the secondary control layer 210, primary control layer 220, and real time controller 230 can be embodied as hardware or software.

The secondary control layer 210 can calculate an initial DCT values for the coming billing cycle. The secondary control layer 210 can estimate the initial DCT values using inside a linear optimization framework. In some embodiments, the secondary control layer 210 can estimate the initial DCT values using historical data. The historical data can relate to the power consumption by the load over a period of time. In some embodiments, the historical data can include previous charging data under ideal conditions. In some embodiments, the historical data can include the normal power consumption for the load. The historical data can include a schedule of activities that take place at the load and the amount of power consumed by each activity. In some embodiments, the historical data can include the ideal charging pattern for a battery array for demand charge minimization and state of charge minimization. In some embodiments, the initial DCT values can be estimated under optimal conditions. In some embodiments, the DCT values can include an anytime DCT, a partial time DCT, and a peak time DCT. Once the secondary control layer 210 has estimated the DCT values for the upcoming billing period, the secondary control layer 210 can transmit the DCT information to the primary layer controller.

The primary layer controller 220 can calculate a charge/discharge schedule for the battery array 108. The primary layer controller 220 can also modify the initial DCT values and determine a battery charge/discharge pattern. The battery charge/discharge pattern is the ideal battery array 108 charging and discharging intervals for demand charge minimization while extending the lifespan of the batteries based on the historical operation data. In some embodiments, the battery charge/discharge pattern is the ideal daily battery array 108 charging and discharging intervals for demand charge minimization while extending the lifespan of the batteries. The primary layer controller 220 can then calculate the charge/discharge schedule. The charge/discharge schedule can be implemented with the battery array 108. The charge/discharge schedule can be calculated to minimize DCT violations while following the charge/discharge pattern as closely as possible without causing any violations. The violations can be embodied as demand charge violations, battery violations, load violations, or any other type of violations. Once the modified DCT values and the battery charge/discharge schedule have been determined, the primary controller layer 220 can transmit the modified DCT values battery charge/discharge schedule and the to the real time controller 230.

The real time controller 230 can implement the received battery charge/discharge schedule with the battery array 108. The real time controller 230 can receive the modified DCT values and the charge/discharge schedule from primary layer. In some embodiments, the real time controller 230 may check the DCT values and then modify the charge/discharge schedule to keep the power consumed from the grid or utility pole 102 below the DCT values. In some embodiments, the real time controller may receive data related to the battery array 108. The data may correspond to the states of charge of the battery array 108, the health of the batteries, the current charging/discharging capability of the batteries, or any other information related to the battery array 108. The physical constrains of the battery array 108 are checked against the charge/discharge pattern and the DCT values may be updated based on the physical constraints of the battery. In some embodiments, the DCTs are updated based on the following rules.

DCT_{any}^{next}=max(DCT_{any}^{last},P_{g})

DCT_{any}^{next} is the updated DCT value for any time during the next period. DCT_{any}^{last} is the previous DCT value for any time during the pervious or current period. P_{g} is the power consumed from the grid or utility pole 102. DCT_{any}^{next} is equal to the larger of DCT_{any}^{last} and P_{g}. In other words, if the previous DCT value was greater than the power consumed form the grid, then the previous DCT value can continued to be used. If the power consumed from the grid was greater than the previous DCT value, then a violation has occurred and the updated DCT value should be at least the power consumed from the grid.

$${DCT}_{par}^{next} = \{ \begin{matrix}max ( {DCT}_{par}^{last} , {P}_{g} ) & if current time is partial time \\ {DCT}_{par}^{last} & if current is not partial time\end{matrix}$$

DCTₚₐᵣ^{next} is the updated DCT value for the partial period during the next period. During the partial period, the utility company charges less for power consumption than during the peak period. DCTₚₐᵣ^{last} is the DCT value for the partial period from the previous period. P_{g} is the power consumed from the grid or utility pole 102. If the current time is partial time, then DCTₚₐᵣ^{next} is equal to the greater of DCTₚₐᵣ^{last} and P_{g}. In other words, if the previous DCT value was greater than the power consumed form the grid, then the previous DCT value can continued to be used. If the power consumed from the grid was greater than the previous DCT value, then a violation has occurred and the updated DCT value should be at least the power consumed from the grid. If the current time is not partial time, then DCTₚₐᵣ^{next} is equal to DCTₚₐᵣ^{last}. In other words, the previous DCT value should continue to be the current DCT value.

$${DCT}_{pea}^{next} = \{ \begin{matrix}max ( {DCT}_{pea}^{last} , {P}_{g} ) & if current time is peak time \\ {DCT}_{pea}^{last} & if current is not peak time\end{matrix}$$

DCTₚₑₐ^{next} is the updated DCT value for the peak period during the next period. During the peak period, the utility company charges more for power consumption than during the partial period. DCTₚₑₐ^{last} is the DCT value for the peak period from the previous period. P_{g} is the power consumed from the grid or utility pole 102. If the current time is peak time, then DCTₚₑₐ^{next} is equal to the greater of DCTₚₑₐ^{last} and P_{g}. In other words, if the previous DCT value was greater than the power consumed form the grid, then the previous DCT value can continued to be used. If the power consumed from the grid was greater than the previous DCT value, then a violation has occurred and the updated DCT value should be at least the power consumed from the grid. In the current time is not peak time, then DCTₚₑₐ^{next} is equal to DCTₚₑₐ^{last}. In other words, the previous DCT value should continue to be the current DCT value.

In some embodiments, after the various constraints are checked and the DCT values are updated accordingly, the real time controller 230 may transmit the updated DCT values to the primary control layer 220 of the demand charge management circuitry 110.

In some embodiments, after reviewing the charge/discharge pattern, the real time controller 230 can transmit commands 116 to the battery controller 112. In some embodiments, the real time controller 230 can transmit the charge/discharge schedule to the battery controller 112.

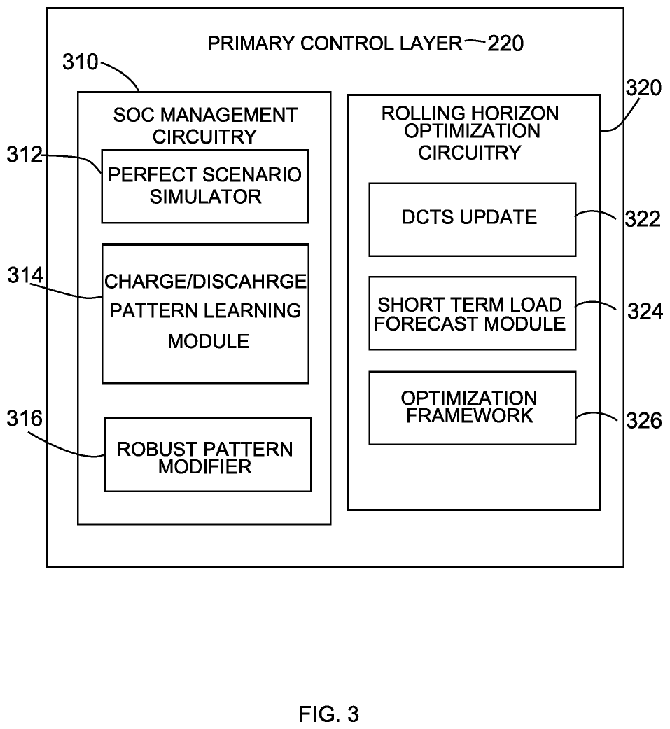

Referring now to FIG. 3, the primary control layer 220 can include of a SOC management circuitry 310 and a rolling horizon optimization circuitry 310.

The SOC management circuitry 310 can learn the daily pattern for the charge and discharge intervals based on optimal historical data. The SOC management circuitry 310 can generate a charge/discharge pattern for the battery array 108 for minimizing demand charge violations while extending battery life. The SOC management circuitry 310 can include a perfect scenario simulator 312, a charge/discharge pattern learning module 314, and a robust modifier 316.

The perfect scenario simulator 312 can be embodied to obtain profiles based on historical data. The historical data can be a record of the power consumption of the load over a period of time. The historical data can also be a record of battery array 108 performance over a period of time. In some embodiments, the historical data may be a record of the power consumption data over the billing cycle. In some embodiments, the historical data can relate to the consumption of power over the past billing cycle under optimal conditions. In some embodiments, the perfect scenario simulator 312 can generate one or more profiles. The profiles can be embodied as a charge and discharge profile, a peak shaving profile, or any other type of profile relating to power consumption and the BTM-EMS system. The profiles can be obtained using a simulation based on the historical data. The simulation can be run with a primary goal of demand charge minimization and a secondary goal of SOC minimization or extending battery life. The perfect scenario simulator 312 can transmit the profiles to the charge/discharge pattern learning module 314.

The charge/discharge pattern learning module 314 can determine periods in which the battery array 108 can be charged/discharged to minimize the demand charges and the SOC of the battery array 108. The charge/discharge pattern learning module 314 can learn the intervals in which the battery array 108 can be safely discharged without jeopardizing the demand charge savings. The charge/discharge pattern learning module 314 can also learn the period in which the battery array 108 should be fully charged before a coming energy demand peak and intervals in which the peak shaving usually occurs.

In some embodiments, charge/discharge pattern learning module 314 can generate the charge/discharge pattern using an analytical solution. In the analytical solution, charge, discharge and peak shaving period for each day can be extracted from the received profiles. The analytical approach can employ a test threshold to determine the charging intervals, discharging intervals, and peak shaving intervals for the battery array 108. In some embodiments, the charge/discharge pattern learning module 314 can use an artificial intelligence (AI) process to generate the charge/discharge pattern. The AI can be trained by a training module. The training module can receive the profiles and the historical data. The trained model can then generate a charge/discharge pattern based on the received data. In some embodiments, the charge/discharge pattern learning module 314 can identify days in which no peak shaving will occurred. The battery array 108 can be safely discharged on days with no peak shaving without risking DCT violations. The charge/discharge pattern learning module 314 can then output the charge/discharge pattern to the robust pattern modifier 316.

The robust pattern modifier 316 can be embodied to adjust the charge/discharge pattern to account for possible abnormal and unexpected load behaviors. The received charge/discharge pattern is initially calculated based on optimal conditions. In some embodiments, the charge/discharge pattern can be adjusted based on a set of adjustment rules. In some embodiments, the robust pattern modifier 316 can adjust the charge/discharge pattern based on real world battery operations. In some embodiments, the charge/discharge pattern can be adjusted based on abnormal load behavior. The abnormal load behavior can be estimated base on the historical data. In some embodiments, the robust pattern modifier 316 can adjust the charge/discharge pattern to build in a safety margin. For example, a pre-specified charge interval can begin earlier to deal with a possible peak shaving event occurs earlier than expected. The robust pattern modifier 316 can output a modified charge/discharge pattern to the optimization framework 326.

The rolling horizon optimization circuitry 320 can update the initial DCT and calculate a charge/discharge schedule. The rolling horizon optimization circuitry 320 can manage the DCT and charge/discharge schedule while focusing on minimizing DCT violations and minimizing the average SOC of the battery array 108. The rolling horizon optimization circuitry 320 can include of a DCTs update 322, a short term load forecast module 324, and an optimization framework 326. The DCTs update 322 can update the initial DCT values. The DCTs update 322 may also receive updated DCT values. The short term load forecast module 324 can determine and/or receive the forecast of power consumption for an upcoming period of time. The optimization framework 326 can calculate a charge/discharge schedule to be implemented with the battery array 108.

The DCTs update 322 can modify the initial DCT values. The DCTs update 322 can receive the initial DCT values from the secondary control layer 210. In some embodiments, the DCT values can include an anytime DCT, a partial DCT, and a peak DCT. In some embodiments, the DCTs update 322 can multiply the initial DCT by a as the initial DCT adjust coefficient, and wherein a is less than 1. The DCTs update 322 can perform the multiplication to avoid over estimation. In some embodiments, the DCTs update 322 can modify the initial DCT after a DCT violation occurs in real time. In some embodiments, the DCTs update 322 may receive updated DCT values from the real time controller 230. The DCTs updater 322 may transmit the updated DCT values to the optimization framework 326.

The short term load forecast module 324 can generate a load forecast. The load forecast can predict the power consumption by the load 106 over a period of time. In some embodiments, the load forecast can predict the power consumption by the load 106 for a 24 hour period. In some embodiments, the short term load forecast module 324 can use a seasonal ARIMA model and the model parameters are obtained using the maximum likelihood optimization to generate the load forecast. In some embodiments, the short term load forecast module 324 may receive load history data. The short term load forecast module 324 may use the receive load history data to generate a load forecast. In some embodiments, the short term load forecast module 324 may receive data inputted by a user. The user data may identify which load functions are to be run and the power consumption by each load function. The short term load forecast module can then transmits the load force cast to the optimization framework 326.

The optimization framework 326 can calculate an optimal DCT values and a charge/discharge schedule. The optimal DCT values and charge/discharge schedule are calculated with a primary goal of demand charge minimization and a secondary goal of state of charge minimization. The optimization framework 326 can use the received the updated DCT values, load forecast, and charge/discharge pattern to calculate the optimal DCT values and charge/discharge schedule. In some embodiments, the optimization framework 326 may recalculate the optimal DCT values and charge/discharge schedule after a period of time. The period of time may be embodied as 15 minutes, 30 minutes, or any other period of time. The optimization framework 326 can calculate the optimal DCT and battery array 108 charge/discharge schedule for a given period of time. In some embodiments, the period of time may be 24 hours, 48 hours, or any other period of time.

In some embodiments, when the optimization framework 326 calculates the charge/discharge schedule, the optimization framework 326 will attempt to follow the charge/discharge schedule with the received charge/discharge pattern. The charge/discharge pattern was generated under optimal conditions. When calculating the charge/discharge schedule the optimization framework 326 will need to consider the load forecast and the changing DCT values. The optimization framework 326 can calculate the charge/discharge schedule while penalizing and incentivizing battery according to the discharge and charge intervals of the received charge/discharge pattern.

In some embodiments, the optimization framework 326 can calculate the optimal DCT and charge/discharge pattern using the following formulas.

$${Min}_{{P}_{B}} ( {α}_{any} Δ {DCT}_{any} + {α}_{par} Δ {DCT}_{par} + {α}_{pea} Δ {DCT}_{pea} ) + {\sum }_{{t}_{0}}^{T + {t}_{0}} β ( t ) {P}_{b} ( t )$$

Where ΔDCT_{any}, ΔDCTₚₐᵣ and ΔDCTₚₑₐ are increase in the DCTs that should be minimized. ΔDCT_{any} is the change in DCT value for any time. ΔDCTₚₐᵣ is the change in DCT value during partial time. ΔDCTₚₑₐ is the change in DCT value for during peak time. α_{any}(t), αₚₐᵣ(t), αₚₑₐ(t) are tariff rates for the any, partial and peak time peaks. In other words, α_{any}(t), αₚₐᵣ(t), αₚₑₐ(t) may enforce the importance of any, partial and peak time demand charges for different time steps of the optimization. These tariff rates can be determined by the provider utilities to motivate the customers to modify their consumption patterns. Tariffs may have different values for different months of a year. For example the peak time tariff is higher in summers in compare to winters to motivate customers consume less power during the hot summer days when the energy demand is extremely high. In some embodiments, tariff rates can be set by a user. The user can set the tariff rates to decrease the cost over a billing period. The user may set the tariff rates to penalize adjusting the initial demand charge threshold for non-peak times. P_{b}(t) is the power supplied/consumed by the battery array 108. β(t) is a vector of coefficients obtained based on the received learned charge/discharge pattern. The vector of coefficients may be obtained using following rule,

$$β ( t ) = \{ \begin{matrix}ɛ & if t ∈ charging interval in charge / discharge pattern \\ - ɛ & if t ∈ discharging interval in charge / discharge pattern\end{matrix}$$

where ε is an small positive number.

$${Min}_{{P}_{B}} ( {α}_{any} Δ {DCT}_{any} + {α}_{par} Δ {DCT}_{par} + {α}_{pea} Δ {DCT}_{pea} )$$

is minimizing the change in DCT values. The tariff rates are selected to apply a penalty value for changing the DCT values. In other words, the formula attempts to minimize the change in DCT values. In some embodiments, tariff rates are applied to discourage changing the DCT values during non-pea times.

The second part objective function Σₜ_{₀}^{T+t}^{₀}β(t) P_{b}(t) is designed to manage the battery storage SOC using the charge/discharge pattern obtained by the SOC management circuitry. To achieve this goal, β(t) s are assigned based on the received charge/discharge pattern. In the other words, β(t) is assigned to be a small positive value when t belongs to the charging interval and to be a small negative value when t belongs to discharging interval. The formula encourages matching the charge/discharge schedule to the charge/discharge pattern as close as possible. Doing so will encourage minimizing demand charges while extending the battery life of batteries in the battery array 108.

The optimization framework 326 may also satisfy the following equality and inequality constraints while minimizing the objective function to check that the charge/discharge schedule does not cause any type of violation to occur. In some embodiments, other types of constraints may be added to the optimization problem for different system set ups and different customers.

P_{g}(t)≤DCT_{any}∀t∈[t₀,T+t₀]

Where P_{g}(t) is the power from the energy grid or utility pole 102 over time. DCT_{any} is the demand charge threshold for any time during the period. And ∀t∈[t₀,T+t₀] is for all time starting from initial time t₀ over a period of time T. In other words, the formula checks that the power consumed from the utility pole 102 is never greater than the DCT_{any} value over the time period T. If the power from the utility pole 102 is ever greater than the DCT value, then a demand charge violation occurs.

P_{g}(t)≤DCTₚₐᵣ∀t∈Tₚₐᵣ[t₀,T+t₀]

Where DCTₚₐᵣ is the demand charge threshold for during partial time. And ∀t∈Tₚₐᵣ [t₀,T+t₀] is for all time in starting from initial time t₀ over time period T for all time partial time or Tₚₐᵣ. In other words, the formula confirms that over period T whenever partial time occurs that the power consumed from the utility pole 102 is less than the demand charge threshold for partial time. If the power from the utility pole 102 is ever greater than the DCT value, then a demand charge violation occurs.

P_{g}(t)≤DCTₚₑₐₖ∀t∈Tₚₑₐ[t₀,T+t₀]

Where DCTₚₑₐₖ is the demand charge threshold for during peak time. And ∀t∈Tₚₑₐ [t₀,T+t₀] is for all time stating from initial time t₀ over time period T for all time peak time or Tₚₑₐ. In other words, the formula confirms that over period T whenever peak time occurs that the power consumed from the utility pole 102 is less than the demand charge threshold for peak time. If the power from the utility pole 102 is ever greater than the DCT value, then a demand charge violation occurs.

SOC_{b}^{min}≤SOC_{b}(t)≤SOC_{b}^{max}∀t∈[t₀,T+t₀]

Where SOC_{b}^{min} is the minimum state of charge of the battery array 108. SOC_{b}(t) is the current state of charge of the battery array 108 for time t. SOC_{b}^{max} is the maximum state of charge of the battery array 108. And ∀t∈[t₀,T+t₀] is for all time starting from initial time t₀ over a period of time T. In other words, the formula checks that over time period T the state of charge of the battery array 108 stays within a physical constraints of the battery array 108. The charging/discharging schedule of the battery array 108 will cause the state of charge of the battery to fluctuate. If the state of charge of the battery array 108 goes outside the range, the battery array 108 may suffer damage.

P_{b}^{min}≤P_{b}(t)≤P_{b}^{max}∀t∈[t₀,T+t₀]

Where P_{b}^{min} is a negative value and represent the maximum charging ability of the battery. When the battery array 108 is charging, the battery array 108 is consuming power from the grid or utility pole 102. P_{b}(t) is the current power being provided or consumed by the battery array 108. P_{b}^{max} is the maximum power that can be supplied by the battery array 108. And ∀t∈[t₀,T+t₀] is for all time starting from initial time t₀ over a period of time T. In other words, the formula checks that the battery array 108 does not exceed its charging or discharging limits over time period T. If either limit is exceeded, the battery array 108 may be damaged.

P_{g}(t)+P_{b}(t)= [symbol] (t)∀t∈[t₀,T+t₀]

Where P_{g}(t) is the power provided from the grid or utility pole 102 over time. P_{b}(t) is the power provided by the battery array 108 over time. [symbol] (t) is the forecast of the power consumed by the load 106 at time t. And ∀t∈[t₀,T+t₀] is for all time starting from initial time t₀ over a period of time T. In other words, the formula states that the load 106 should consume power equal to about the power provided by the grid and the power provided by the battery array 108.

SOC_{b}(t)=SOC_{b}(t−1)−Δt×P_{b}(t)∀t∈[t₀,T+t₀]

Where SOC_{b} (t) is the state of charge of the battery array 108 at time t. SOC_{b}(t−1) is the state of charge of the battery array 108 at time t−1. Δt is the charge in time. P_{b}(t) is the power provided by the battery array 108 at time t. And ∀t∈[t₀,T+t₀] is for all time starting from initial time t₀ over a period of time T. In other words, the formula provides the current state of charge of the battery array 108 at time t. Δt×P_{b}(t) is the amount of charge provided by the battery array 108 over time Δt and is added to or subtracted from the previous state of charge of the battery array 108 (SOC_{b}(t−1)) is get the current state of charge of the battery array 108 at time t.

DCT_{any}=DCT_{any}⁰+ΔDCT_{any}

Where DCT_{any} is the current demand charge threshold for any time. DCT_{any}⁰ is the initial demand charge threshold for any time. And ΔDCT_{any} is the change in demand charge threshold for any time. In other words, the change in demand charge threshold is added to the initial demand charge threshold to provide the current demand charge threshold for any time.

DCTₚₐᵣ=DCTₚₐᵣ⁰+ΔDCTₚₐᵣ

Where DCTₚₐᵣ is the current demand charge threshold for partial time. DCTₚₐᵣ⁰ is the initial demand charge threshold for partial time. And ΔDCTₚₐᵣ is the change in demand charge threshold for partial time. In other words, the change in demand charge threshold is added to the initial demand charge threshold to provide the current demand charge threshold for partial time.

DCTₚₑₐ=DCTₚₑₐ⁰+ΔDCTₚₑₐ

Where DCTₚₑₐ is the current demand charge threshold for peak time. DCTₚₑₐ⁰ is the initial demand charge threshold for peak time. And ΔDCTₚₑₐ is the change in demand charge threshold for peak time. In other words, the change in demand charge threshold is added to the initial demand charge threshold to provide the current demand charge threshold for peak time.

ΔDCT_{any},ΔDCTₚₐᵣ,ΔDCTₚₑₐ≥0

Where ΔDCT_{any} is the change in the demand charge threshold for any time. ΔDCTₚₐᵣ is the change in the demand charge threshold for partial time. And ΔDCTₚₑₐ is the change in the demand charge threshold for peak time. In other words, the formula checks that the change in all of the demand charge threshold are not negative.

In some embodiments, the optimization framework 326 can calculate the charge/discharge schedule of the battery array in the way it minimizes (a) the DCTs, (b) satisfying all optimization constraints, (c) the charge and discharge schedule follows the charge/discharge pattern calculated by the SOC management circuitry 310. In some embodiments, the last goal is achieved by last term of the objective function represented in [0059].

In some embodiments, the received charge/discharge pattern can include a level of charge for the battery array 108 in addition to when the battery array 108 should be charge/discharged. The optimization framework 326 may calculate the charge/discharge schedule to match the level of charge as close as possible to the charge/discharge array 108 without risking any violations.

In some embodiments, the charge/discharge schedule can include specific charging commands 116 for each individual battery in the battery array 108. The optimization framework 326 can receive data related to the health of each individual battery in the battery array 108. The optimization framework 326 can first establish a charge/discharge schedule which closely follows the received charge/discharge pattern. Then the optimization framework 326 may adjust the charge/discharge schedule for each individual battery in the battery array 108 based on the health of each individual battery. For example, the charge/discharge schedule may keep batteries at low health at a lower state of charge to perverse them. The charge/discharge schedule may use the batteries at greatest health to provide the majority of power to the load.

The optimization framework 326 can output the modified DCT values and charge/discharge schedule to the real time controller 230.

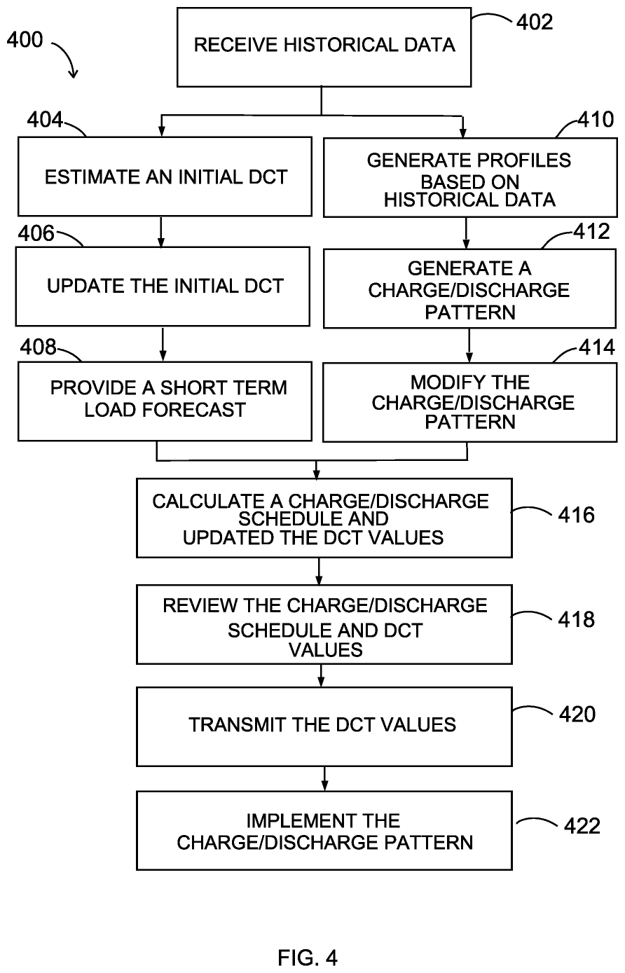

Referring now to FIG. 4, a block/flow diagram showing a high-level method 400 for determining a charge/discharge schedule for the battery array with a goal of demand charge minimization while extending battery life is illustratively depicted in accordance with an embodiment of the present invention.

In some embodiments, in block 402, the demand charge management circuitry may receive historical data. The historical data may relate to power consumption of the load, demand charge data, previous charge/discharge information relating to the battery array or any other information relevant to determining a charge/discharge pattern for the battery array. In some embodiments, the historical data may be related to the previous billing cycle. In some embodiments, the historical data may represent the load under optimal conditions. The historical data may be received form a variety of sources. In some embodiments, the historical data may be received from a utility company, from the load, and/or from a smart meter. The demand charge management circuitry may store the historical data for later user. The method then proceeds to blocks 404 and 410.

In block 404, an initial demand charge threshold (DCT) can be determined. The DCT can be determined with a goal of demand charge minimization. In some embodiments, the DCT can be determined based on the received historical data. In some embodiments, the initial DCT can be determine based on the previous billing cycle power consumption data. In some embodiments, the initial DCT may be based on optimal conditions. In some embodiments, the initial DCT can include a plurality of DCT values.

In block 406, the initial DCT can be updated. The initial DCT can a include a plurality of DCT values. In some embodiments, the initial DCT can include an any time DCT, a partial time DCT, and an peak time DCT. In some embodiments, the initial DCT can be multiplied by a and where a is a positive number less than 1. The initial DCT is updated to avoid over estimation. In some embodiments, the initial DCT may be updated with received DCT values.

In block 408, a short term load forecast is provided. In some embodiments, the short term load forecast represent the next 24 hours. In some embodiments, the a seasonal ARIMA model is used. The model parameters may be obtained using the maximum likelihood optimization. In some embodiments, a user may provide information about the short term load forecast. The user may provide of schedule of operations that will occur the next day along with the time and energy consumption. The short term load forecast may be later user in block 416.

In block 410, profiles are generated based on the received historical data. The profiles may be charge and discharge profiles, peak shaving profiles, daily load profiles, or any other type of profile related to power consumption and BTM-ESS. In some embodiments, the profiles may be generated by a perfect scenario simulator. A simulation may simulate a period of time of operation assuming that the load profile was known for each stop of the operation. The simulation may have the objective function to minimize the demand charges and SOC minimization. The profiles may be generated from the simulation.

In block 412, a charge/discharge pattern is learned from the profiles generated in block 410. The charge/discharge pattern may indicate when a battery array can be discharge without jeopardizing the demand charge savings. The charge/discharge pattern may also indicate when the battery array should charge before upcoming peaks where peak shaving should occur. The charge/discharge pattern can represent the ideal charging schedule for a battery array for demand charge minimization while extending battery life.

In some embodiments, the daily load, shaved load, charge/discharge profiles for a previous time period may be used to learn the charge/discharge pattern. In some embodiments, the charge/discharge pattern may be learned using analytical approaches. In an analytical approach, a daily battery charge profile and shaved load profiles may be extracted and then the charge, discharge, and peak shaving period for each day may be identified. Then a threshold test may be employed to determine the charge/discharge pattern. In some embodiments, an artificial intelligence method may be used to learn the charge/discharge profile. The artificial intelligence method may extract features from the profiles. The features may then be passed to a training model. The training model may then obtain the best charge/discharge pattern. In some embodiments, the learned charge/discharge pattern may identify day in which no peak shaving will occur. On those days, the battery array can be discharge without risking DCT violations.

In block 414, the charge/discharge pattern from block 412 may be modified. The charge/discharge pattern may be modified to add a level of robustness. In some embodiments, the charge/discharge pattern may be modified to account for the real world properties of the battery array. For example, as the batteries degrade they make take longer charge fully. In some embodiments, the charge/discharge pattern may be modified to account for abnormal or unexpected load behaviors. The charge/discharge pattern may be modified based on a rule set. For example, a pre-specified charge interval may be added to each charging interval in case the peak shaving event occurs earlier than expected.

Referring now to block 416, a charge/discharge schedule and updated DCT may be calculated. The charge/discharge schedule may be implemented with the battery array. The charge/discharge schedule and updated DCT can be calculated with the initial DCT, short term load forecast, and charge/discharge pattern. In some embodiments, the charge/discharge schedule and updated DCT may be recalculated after a period of time. In some embodiments, the charge/discharge schedule and updated DCT may be recalculated every 15 minutes.

In some embodiments, the charge/discharge schedule and updated DCT can calculate using the following formulas.

$${Min}_{{P}_{B}} ( {α}_{any} Δ {DCT}_{any} + {α}_{par} Δ {DCT}_{par} + {α}_{pea} Δ {DCT}_{pea} ) + {\sum }_{{t}_{0}}^{T + {t}_{0}} β ( t ) {P}_{b} ( t )$$

Where ΔDCT_{any}, ΔDCTₚₐᵣ and ΔDCTₚₑₐ are increase in the DCTs that should be minimized. ΔDCT_{any} is the change in DCT value for any time. ΔDCTₚₐᵣ is the change in DCT value during partial time. ΔDCTₚₑₐ is the change in DCT value for during peak time. α_{any}(t), αₚₐᵣ(t), αₚₑₐ(t) are tariff rates for the any, partial and peak time peaks. In other words, α_{any}(t), αₚₐᵣ(t), αₚₑₐ(t) may enforce the importance of any, partial and peak time demand charges for different time steps of the optimization. These tariff rates can be determined by the provider utilities to motivate the customers to modify their consumption patterns. Tariffs may have different values for different months of a year for example the peak time tariff is higher in summers in compare to winters to motivate customers consume less power during the hot summer days when the energy demand is extremely high. In some embodiments, tariff rates can be set by a user. The user can set the tariff rates to decrease the cost over a billing period. The user may set the tariff rates to penalize adjusting the initial demand charge threshold for non-peak times. P_{b}(t) is the power supplied/consumed by the battery array 108. β(t) is a vector of coefficients obtained based on the received learned charge/discharge pattern. The vector of coefficients may be obtained using following rule,

$$β ( t ) = \{ \begin{matrix}ɛ & if t ∈ charging interval in charge - discharge pattern \\ - ɛ & if t ∈ discharging interval in charge - discharge pattern\end{matrix}$$

where ε is an small positive number.

$${Min}_{{P}_{B}} ( {α}_{any} Δ {DCT}_{any} + {α}_{par} Δ {DCT}_{par} + {α}_{pea} Δ {DCT}_{pea} )$$

is minimizing the change in DCT values. The tariff rates are selected to apply a penalty value for changing the DCT values. In other words, the formula attempts to minimize the change in DCT values. In some embodiments, the tariff rates may discourage changing DCT values during non-peak times. The values are minimized to encourage the charge/discharge schedule to match the receive charge/discharge pattern.

The second part objective function Σₜ_{₀}^{T+t}^{₀}β(t) P_{b}(t) is designed to manage the battery storage SOC using the charge/discharge pattern obtained by the SOC management circuitry. To achieve this goal, β(t) s are assigned based on the received charge/discharge pattern. In the other words, β(t) is assigned to be a small positive value when t belongs to the charging interval and to be a small negative value when t belongs to discharging interval. The formula encourages matching the charge/discharge schedule to the charge/discharge pattern as close as possible. Doing so will encourage minimizing demand charges while extending the battery life of batteries in the battery array.

The optimization framework 326 must also satisfy the following equality and inequality constraints while minimizing the objective function to check that the charge/discharge schedule does not cause any type of violation to occur. In some embodiments, other types of constraints may be added to the optimization problem for different system set ups and different customers.

P_{g}(t)≤DCT_{any}∀t∈[t₀,T+t₀]

Where P_{g}(t) is the power from the energy grid or utility pole over time. DCT_{any} is the demand charge threshold for any time during the period. And ∀t∈[t₀,T+t₀] is for all time starting from initial time t₀ over a period of time T. In other words, the formula checks that the power consumed from the utility pole is never greater than the DCT_{any} value over the time period T. If the power from the utility pole is ever greater than the DCT value, then a demand charge violation occurs.

P_{g}(t)≤DCTₚₐᵣ∀t∈Tₚₐᵣ[t₀,T+t₀]

Where DCTₚₐᵣ is the demand charge threshold for during partial time. And ∀t∈Tₚₐᵣ [t₀,T+t₀] is for all time in starting from initial time t₀ over time period T for all time partial time or Tₚₐᵣ. In other words, the formula confirms that over period T whenever partial time occurs that the power consumed from the utility pole is less than the demand charge threshold for partial time. If the power from the utility pole is ever greater than the DCT value, then a demand charge violation occurs.

P_{g}(t)≤DCTₚₑₐₖ∀t∈Tₚₑₐ[t₀,T+t₀]

Where DCTₚₑₐₖ is the demand charge threshold for during peak time. And ∀t∈Tₚₑₐ [t₀,T+t₀] is for all time stating from initial time t₀ over time period T for all time peak time or Tₚₑₐ. In other words, the formula confirms that over period T whenever peak time occurs that the power consumed from the utility pole is less than the demand charge threshold for peak time. If the power from the utility pole is ever greater than the DCT value, then a demand charge violation occurs.

SOC_{b}^{min}≤SOC_{b}(t)≤SOC_{b}^{max}∀t∈[t₀,T+t₀]

Where SOC_{b}^{min} is the minimum state of charge of the battery array. SOC_{b}(t) is the current state of charge of the battery array 108 for time t. SOC_{b}^{max} is the maximum state of charge of the battery array 108. And ∀t∈[t₀,T+t₀] is for all time starting from initial time t₀ over a period of time T. In other words, the formula checks that over time period T the state of charge of the battery array stays within a physical constraints of the battery array. The charging/discharging schedule of the battery array will cause the state of charge of the battery to fluctuate. If the state of charge of the battery array goes outside the range, the battery array 108 may suffer damage.

P_{b}^{min}≤P_{b}(t)≤P_{b}^{max}∀t∈[t₀,T+t₀]

Where P_{b}^{min} is a negative value and represent the maximum charging ability of the battery. When the battery array 108 is charging, the battery array is consuming power from the grid or utility pole 102. P_{b}(t) is the current power being provided or consumed by the battery array. P_{b}^{max} is the maximum power that can be supplied by the battery array. And ∀t∈[t₀,T+t₀] is for all time starting from initial time t₀ over a period of time T. In other words, the formula checks that the battery array does not exceed its charging or discharging limits over time period T. If either limit is exceeded, the battery array 108 may be damaged.

P_{g}(t)+P_{b}(t)= [symbol] (t)∀t∈[t₀,T+t₀]

Where P_{g}(t) is the power provided from the grid or utility pole 102 over time. P_{b}(t) is the power provided by the battery array over time. [symbol] (t) is the forecast of power consumed by the load at time t. And ∀t∈[t₀,T+t₀] is for all time starting from initial time t₀ over a period of time T. In other words, the formula states that the load 106 should consume power equal to about the power provided by the grid and the power provided by the battery array 108.

SOC_{b}(t)=SOC_{b}(t−1)−Δt×P_{b}(t)∀t∈[t₀,T+t₀]

Where SOC_{b}(t) is the state of charge of the battery array at time t. SOC_{b}(t−1) is the state of charge of the battery array at time t−1. Δt is the charge in time. P_{b}(t) is the power provided by the battery array at time t. And ∀t∈[t₀,T+t₀] is for all time starting from initial time t₀ over a period of time T. In other words, the formula provides the current state of charge of the battery array 108 at time t. Δt×P_{b}(t) is the amount of charge provided by the battery array over time Δt and is added to or subtracted from the previous state of charge of the battery array (SOC_{b}(t−1)) is get the current state of charge of the battery array at time t.

DCT_{any}=DCT_{any}⁰+ΔDCT_{any}

Where DCT_{any} is the current demand charge threshold for any time. DCT_{any}⁰ is the initial demand charge threshold for any time. And ΔDCT_{any} is the change in demand charge threshold for any time. In other words, the change in demand charge threshold is added to the initial demand charge threshold to provide the current demand charge threshold for any time.

DCTₚₐᵣ=DCTₚₐᵣ⁰+ΔDCTₚₐᵣ

Where DCTₚₐᵣ is the current demand charge threshold for partial time. DCTₚₐᵣ⁰ is the initial demand charge threshold for partial time. And ΔDCTₚₐᵣ is the change in demand charge threshold for partial time. In other words, the change in demand charge threshold is added to the initial demand charge threshold to provide the current demand charge threshold for partial time.

DCTₚₑₐ=DCTₚₑₐ⁰+ΔDCTₚₑₐ

Where DCTₚₑₐ is the current demand charge threshold for peak time. DCTₚₑₐ⁰ is the initial demand charge threshold for peak time. And ΔDCTₚₑₐ is the change in demand charge threshold for peak time. In other words, the change in demand charge threshold is added to the initial demand charge threshold to provide the current demand charge threshold for peak time.

ΔDCT_{any},ΔDCTₚₐᵣ,ΔDCTₚₑₐ≥0

Where ΔDCT_{any} is the charge in the demand charge threshold for any time. ΔDCTₚₐᵣ is the change in the demand charge threshold for partial time. And ΔDCTₚₑₐ is the change in the demand charge threshold for peak time. In other words, the formula checks that the change in all of the demand charge threshold are not negative.

In some embodiments, the optimization framework 326 can calculate the charge/discharge schedule of the battery array in the way that it minimizes (a) the DCTs, (b) satisfying all optimization constraints, (c) and charge and discharge schedule follows the charge/discharge pattern calculated by the SOC management circuitry 310. In some embodiments, the last goal is achieved by last term of the objective function represented in [0059].

In some embodiments, the received charge/discharge pattern can include a level of charge for the battery array in addition to when the battery array should be charge/discharged. The method may calculate the charge/discharge schedule to match the level of charge as close as possible to the charge/discharge array without risking any violations.

In some embodiments, the charge/discharge schedule can include specific charging commands for each individual battery in the battery array. An initial chare/discharge schedule can first be established to closely match the received charge/discharge pattern. The charge/discharge schedule may be adjusted for each individual battery in the battery array based on the health of each individual battery. For example, the charge/discharge schedule may keep batteries at low health at a lower state of charge to perverse them. The charge/discharge schedule may use the batteries at greatest health to provide the majority of power to the load.

In block 418, the charge/discharge pattern and the DCT values may be reviewed. The charge/discharge pattern may be checked against the modified DCT to confirm that the demand charge minimization. In some embodiments, the charge/discharge pattern may be checked against the physical constraints of the batteries in the battery array. In some embodiments, the DCTs are updated based on the following rules.

DCT_{any}^{next}=max(DCT_{any}^{last},P_{g})

DCT_{any}^{next} is the updated DCT value for any time during the next period. DCT_{any}^{last} is the previous DCT value for any time during the pervious or current period. P_{g} is the power consumed from the grid or utility pole. DCT_{any}^{next} is equal to the larger of DCT_{any}^{last} and P_{g}. In other words, if the previous DCT value was greater than the power consumed form the grid, then the previous DCT value can continued to be used. If the power consumed from the grid was greater than the previous DCT value, then a violation has occurred and the updated DCT value should be at least the power consumed from the grid.

$${DCT}_{par}^{next} = \{ \begin{matrix}max ( {DCT}_{par}^{last} , {P}_{g} ) & if current time is partial time \\ {DCT}_{pea}^{last} & if current time is not not partial time\end{matrix}$$

DCTₚₐᵣ^{next} is the updated DCT value for the partial period during the next period. During the partial period, the utility company charges less for power consumption than during the peak period. DCTₚₐᵣ^{last} is the DCT value for the partial period from the previous period. P_{g} is the power consumed from the grid or utility pole. If the current time is partial time, then DCTₚₐᵣ^{next} is equal to the greater of DCTₚₐᵣ^{last} and P_{g}. In other words, if the previous DCT value was greater than the power consumed form the grid, then the previous DCT value can continued to be used. If the power consumed from the grid was greater than the previous DCT value, then a violation has occurred and the updated DCT value should be at least the power consumed from the grid. If the current time is not partial time, then DCTₚₐᵣ^{next} is equal t₀ DCTₚₐᵣ^{last}. In other words, the previous DCT value should continue to be the current DCT value.

$${DCT}_{pea}^{next} = \{ \begin{matrix}max ( {DCT}_{pea}^{last} , {P}_{g} ) & if current time is peak time \\ {DCT}_{pea}^{last} & if current is not peak time\end{matrix}$$

DCTₚₑₐ^{next} is the updated DCT value for the peak period during the next period. During the peak period, the utility company charges more for power consumption than during the partial period. DCTₚₑₐ^{last} is the DCT value for the peak period from the previous period. P_{g} is the power consumed from the grid or utility pole. If the current time is peak time, then DCTₚₑₐ^{next} is equal to the greater of DCTₚₑₐ^{last} and P_{g}. In other words, if the previous DCT value was greater than the power consumed form the grid, then the previous DCT value can continued to be used. If the power consumed from the grid was greater than the previous DCT value, then a violation has occurred and the updated DCT value should be at least the power consumed from the grid. In the current time is not peak time, then DCTₚₑₐ^{next} is equal to DCTₚₑₐ^{next}. In other words, the previous DCT value should continue to be the current DCT value.

In block 420, the DCT values may be transmitted. In some embodiments, the DCT values can be transmitted to a computer device to be used when updating the initial DCT in block 406.

In block 422, the charge/discharge schedule may be implemented. In some embodiments, the charge/discharge schedule may be transmitted to a battery controller. The battery controller would then implement the charge/discharge schedule with the battery array. In some embodiments, the demand charge management circuitry may implement the charge/discharge schedule with the battery array.

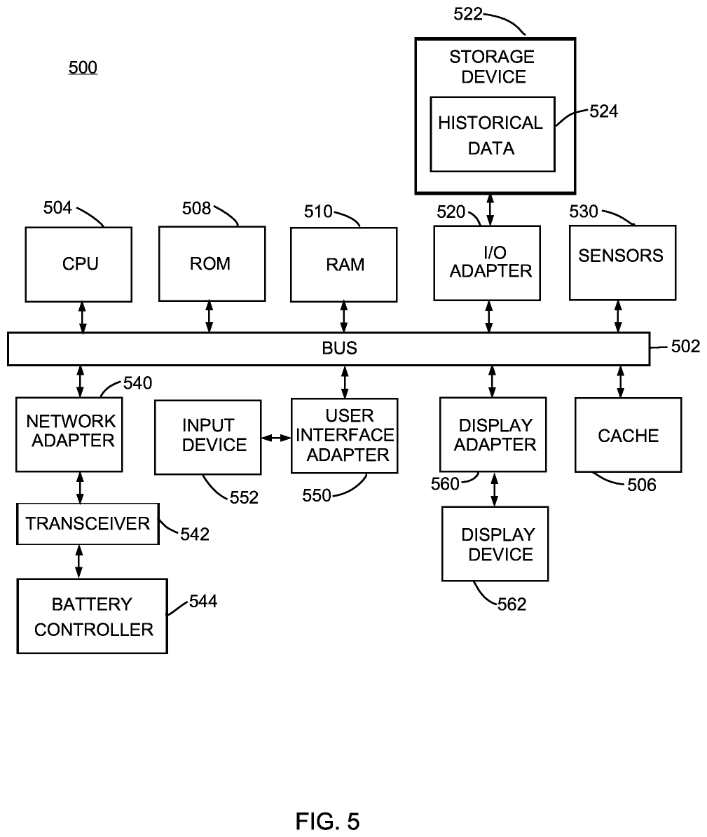

Referring to FIG. 5, an exemplary processing system 500 to which the present principles may be applied is illustratively depicted in accordance with one embodiment of the present invention.

In some embodiments, the processing system 500 can include at least one processor (CPU) 504 operatively coupled to other components via a system bus 502. A cache 506, a Read Only Memory (ROM) 508, a Random Access Memory (RAM) 510, an input/output (I/O) adapter 520, sensors 530, a network adapter 540, a user interface adapter 550, and a display adapter 560, are operatively coupled to the system bus 502.

A storage device 522 is operatively coupled to system bus 502 by the I/O adapter 520. The storage device 522 can be any of a disk storage device (e.g., a magnetic or optical disk storage device), a solid state magnetic device, and so forth. The storage device 522 can be the same type of storage device or different types of storage devices.

Historical data 524 can be stored on the storage device 522. The historical data 524 can relate to the power consumption by the load. In some embodiments, the historical data 524 can include the times which the local utility company considers peak time or partial time. In some embodiments, the historical data 524 can include the normal power consumption for the load. The historical data 524 can include a schedule of activities that take place at the load and the amount of power consumed by each activity. In some embodiments, the historical data 524 can include the ideal charging pattern for a battery array 544 for demand charge minimization and state of charge minimization.

The sensors 530 can be embodied as any type of sensors. In some embodiments, the sensors may be embodied as current sensors, voltage sensor, temperature sensors, etc. The sensors 530 can provided data to the processing system 500 related to power consumption, power generation, and/or the physical constraints of the batteries.

A transceiver 542 is operatively coupled to system bus 502 by network adapter 540. A display device 562 is operatively coupled to system bus 502 by display adapter 560.

The processing system 500 can be coupled to a battery controller 544 by the transceiver 542. The processing system 500 can transmit commands to the battery controller 544. The commands can indicate for the battery controller 544 to charge or discharge the batteries. In some embodiments, the commands can indicate for the battery controller 544 to charge the batteries to specific level of charge. In some embodiments, the commands can indicate for the battery controller 544 to charge each individual battery to specific level of charge.

A user input device 552 are operatively coupled to system bus 502 by user interface adapter 550. The user input device 552 can be any of a keyboard, a mouse, a keypad, an image capture device, a motion sensing device, a microphone, a device incorporating the functionality of at least two of the preceding devices, and so forth. Of course, other types of input devices can also be used, while maintaining the spirit of the present principles. The user input device 552 can be the same type of user input device or different types of user input devices. The user input device 552 are used to input and output information to and from system 500.

Of course, the processing system 500 may also include other elements (not shown), as readily contemplated by one of skill in the art, as well as omit certain elements. For example, various other input devices and/or output devices can be included in processing system 500, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized as readily appreciated by one of ordinary skill in the art. These and other variations of the processing system 500 are readily contemplated by one of ordinary skill in the art given the teachings of the present principles provided herein.

Moreover, it is to be appreciated that systems in FIGS. 1, 2, and 3 respectively, are systems for implementing respective embodiments of the present invention. Part or all of processing system 500 may be implemented in one or more of the elements of systems in FIGS. 1, 2, and 3, according to various embodiments of the present invention.

Further, it is to be appreciated that processing system 500 may perform at least part of the methods described herein including, for example, at least part of methods 400 of FIG. 4, respectively.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A method for demand charge minimized operations while extending battery life, comprising:
determining a demand charge threshold based on received historical data;
generating a charging pattern for a battery array from the historical data, the generating further comprising:
simulating a power consumption of a load over a period of time from the historical data;
extracting a charge profile and a peak shaving profile from the simulation; and
learning a charging pattern from the charge profile and the peak shaving profile, the charging pattern including optimal charging and discharging commands to minimize demand charge violations and minimize a state of charge of the battery array;
calculating a charging schedule for the battery array based on the demand charge threshold, a short term load profile, and the charging pattern, the charging schedule being calculated to follow the charging pattern without exceeding the demand charge threshold; and
transmitting commands to a battery controller in accordance with the charging schedule.

2. The method as recited in claim 1, wherein the charging schedule is calculated based, in part, on physical constraints of the battery array.

3. The method as recited in claim 1, wherein the charging pattern further includes an optimal level of charge for the battery array.

4. The method as recited in claim 1, further comprising receiving battery array health data and wherein the battery array includes a plurality of batteries.

5. The method as recited in claim 4, wherein the charging schedule is calculated based, in part, on the received battery array health data and the commands instruct the battery controller when to charge and discharge each individual battery in the battery array over a period of time.

6. The method as recited in claim 4, wherein the charging schedule is calculated based, in part, on the received battery array health data and the commands instruct the battery controller to charge each individual battery in the battery array to a level of charge.

7. The method as recited in claim 1, further comprising adjusting the demand charge threshold based on the short term load forecast.

8. The method as recited in claim 1, further comprising adjusting the demand charge threshold based on a tariff value, wherein the tariff value penalizes adjusting the demand charge threshold for non-peak times.

9. The method as recited in claim 1, wherein to minimize demand charge violations is a primary objective and to minimize an average state of charge of the battery array is a secondary objective.

10. A system for demand charge minimized operations while extending battery life, comprising:
a processor device operatively coupled to a non-transitory computer-readable storage medium, the processor being configured to:
determine, using a secondary control layer, a demand charge threshold based on received historical data;
generate, using a primary control layer, a charging pattern for a battery array from the historical data, to generate further comprising to:
simulate a power consumption of a load over a period of time from the historical data;
extract a charge profile and a peak shaving profile from the simulation; and
learn a charging pattern from the charge profile and the peak shaving profile, the charging pattern including optimal charging and
discharging commands to minimize demand charge violations and
minimize a state of charge of the battery array;
calculate, using the primary control layer, a charging schedule for the battery array based on the demand charge threshold, a short term load profile, and the charging pattern, the charging schedule being calculated to follow the charging pattern without exceeding the demand charge threshold; and
transmit, using a real time controller commands to a battery controller in accordance with to the charging schedule.

11. The system as recited in claim 10, wherein the charging schedule is calculated based, in part, on physical constraints of the battery array.

12. The system as recited in claim 10, wherein the charging pattern further includes an optimal level of charge for the battery array.

13. The system as recited in claim 10, wherein the processor is further configured to receive battery array health data and wherein the battery array includes a plurality of batteries.

14. The system as recited in claim 13, wherein the charging schedule is calculated based, in part, on the received battery array health data and the commands instruct the battery controller to charge each individual battery in the battery array to a level of charge.

15. The system as recited in claim 13, wherein the charging schedule is calculated based, in part, on the received battery array health data and the commands instruct the battery controller when to charge and discharge each individual battery in the battery array over a period of time.

16. The system as recited in claim 10, wherein the processor is further configured to adjust the demand charge threshold based on a receive short term load forecast.

17. The system as recited in claim 10, wherein the processor is further configured to adjust the demand charge threshold based on a tariff value, wherein the tariff value penalizes adjusting the initial demand charge threshold for non-peak times.

18. A non-transitory computer readable storage medium comprising a computer readable program for demand charge minimized operations while extending battery life, comprising:
determining a demand charge threshold based on received historical data;
generating a charging pattern for a battery array from the historical data, the generating further comprising:
simulating a power consumption of a load over a period of time from the historical data;
extracting a charge profile and a peak shaving profile from the simulation; and
learning a charging pattern from the charge profile and the peak shaving profile, the charging pattern including optimal charging and discharging commands to minimize demand charge violations and minimize a state of charge of the battery array;
calculating a charging schedule for the battery array based on the demand charge threshold, a short term load profile, and the charging pattern, the charging schedule being calculated to follow the charging pattern without exceeding the demand charge threshold; and
transmitting commands to a battery controller in accordance with the charging schedule.

19. The computer readable storage medium as recited in claim 18, wherein the charging schedule is calculated based, in part, on physical constraints of the battery array.

20. The computer readable storage medium as recited in claim 18, wherein the charging pattern further includes an optimal level of charge for the battery array.
